(19) United States
(12) Patent Application Publication
(10) Pub. No.: US 2008/0142481 A1
(43) Pub. Date: Jun. 19, 2008

(54) IN-SITU PARTICLE COLLECTOR

(76) Inventors: John M. White, Hayward, CA (US); Soo Young Choi, Fremont, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/612,066

(22) Filed: Dec. 18, 2006

(51) Int. Cl. H01L 21/306; C03C 15/00

(52) U.S. Cl. 216/67; 156/345.43

(57) ABSTRACT

A plasma-processing chamber is configured with a particle collection conductor to remove charged particles from the chamber during plasma processing of substrates. The particle collection conductor is positioned in a processing region of the chamber and a power supply applies a DC bias to the conductor when plasma is present in the processing region. The conductor may comprise aluminum, and the power supply may be controlled by a plasma controller of the plasma-processing chamber. In one aspect, the conductor may be configured to translate through the processing region during substrate processing. A method is also provided for removing particles from the processing region of a plasma-processing chamber, comprising positioning a substrate in a processing chamber, flowing a processing gas into the processing chamber, generating a plasma in the processing chamber, and applying a DC bias to a particle collection conductor positioned in the processing chamber.

### BACKGROUND OF THE INVENTION

1. Field of the Invention

Embodiments of the present invention generally relate to the fabrication of integrated circuits and particularly to the removal of particles from a vacuum processing chamber.

2. Description of the Related Art

Plasma chambers are commonly used to process substrates for the manufacture of flat panel displays, solar panels, and semiconductor devices. Plasma chambers are vacuum chambers that process a substrate either by depositing one or more materials onto the substrate or by selectively removing materials from the surface of the substrate. Examples of such chambers include physical vapor deposition (PVD), plasma-enhanced chemical vapor deposition (PECVD), and plasma etch chambers.

During plasma processing of substrates, particles as small as 1 micrometer in diameter and below are generally suspended in the plasma and contaminate substrates during and immediately after plasma processing of substrates. Particles may be formed in the bulk plasma or flake off of the interior surfaces of the process chamber. During silane (SiH₄) based PECVD processes, for example, radical silicon (Si*) atoms disassociated from the silane gas may nucleate with other Si* atoms to form solid particles in the plasma. In another example, temperature fluctuations of interior surfaces during PVD-processing of substrates encourages flaking of previously deposited materials. In yet another example, during PECVD deposition of a-C:H films, particles are generated in the bulk plasma due to gas phase polymerization of —CHₓ species. Other reactions between compounds formed during plasma processing may also produce unwanted particles. In each case, the particles formed in the plasma-processing chamber naturally gain an electrical charge in the plasma and, thus, remain suspended in the plasma during processing.

When plasma power is turned off and plasma is extinguished in a processing chamber, these particles tend to fall on and contaminate the substrate surface due to gravitational forces during post-processing chamber pump-down. Substrates typically processed in vacuum chambers, such as semiconductor wafers, flat panel displays, and solar cells, are easily damaged by the presence of such particles on their surfaces. Therefore there is an on-going effort to minimize the number and size of particles that contaminate substrates during processing.

U.S. Pat. No. 6,893,532 illustrates one attempt to control particle contamination of substrates during plasma processing. A particle-collecting electrode and a particle-drawing electrode are positioned inside a plasma-processing chamber and proximate to a substrate to attract and contain particles suspended in the chamber. FIG. 1A is a partial sectional side view of a plasma chamber 100 incorporating the apparatus described in U.S. Pat. No. 6,893,532. FIG. 1B is a perspective sectional view of the particle-collecting electrode positioned in plasma chamber 100. Referring to FIGS. 1A and 1B, a particle-collecting electrode 104 is a hollow structure positioned around the periphery of a substrate 111 and mounted on a hollow attaching stay 112. Hollow attaching stay 112 fluidly couples the interior volume 104A of particle-collecting electrode 104 to a vacuum source, such as a turbo-molecular vacuum pump (not shown). A particle-drawing electrode 115 is positioned inside particle-collecting electrode 104. The plasma-processing region 121 of plasma chamber 100 is generally defined as the region between an upper electrode 102 and a substrate support 103. A plasma 120 is generated inside plasma-processing region 121 during processing of substrates. Plasma 120 may be a DC plasma, such as used for PVD applications, or an RF plasma, which is more commonly used for etch and PECVD applications.

In operation, particle-collecting electrode 104 and particle-drawing electrode 115 are maintained at voltages necessary to attract particles 130 suspended in plasma 120 through openings 113 during plasma processing of substrate 111. The interior volume 104A of particle-collecting electrode 104 is intended to act as a storage region for the captured particles, which may then be removed from plasma chamber 100 by vacuum pumping via hollow attaching stay 112.

Because the apparatus of U.S. Pat. No. 6,893,532 requires an additional internal enclosure, i.e. particle-collecting electrode 104, as well as additional vacuum pumping conduits, such as hollow attaching stay 112, the cost and complexity of a plasma-processing chamber is substantially increased when this apparatus is used to reduce particle contamination of substrates. Also, particle-collecting electrode 104 may increase the pump-down time of the process chamber, thereby reducing the time available for substrate processing.

Moreover, the removal of collected particles from interior volume 104A of particle-collecting electrode 104 by a conduit fluidly coupled to a vacuum pump is not a robust solution. Captured particles are generally not completely removed from a plasma chamber using the apparatus described above, but instead accumulate in interior volume 104A of particle-collecting electrode 104. While under vacuum, which for plasma-processing chambers is the normal condition, fluidly coupling the interior volume of a particle-collecting electrode to a vacuum source produces virtually no drag forces on particles that have accumulated in said interior volume. Therefore no mechanical motivation is present to dislodge and remove such particles from the particle-collecting electrode. This is because fluid drag forces on a particle are a strong function of particle size and on the density of the impinging fluid. As stated above, the size of contaminating particles is very small, and the density of any gases in a plasma chamber under vacuum is extremely low. And while higher density gases may be used for purging particles from the interior volume of a particle-collecting electrode, such purging runs the risk of relocating a substantial portion of the unwanted particles back into the plasma-processing region of the plasma chamber. Therefore, unwanted particles generally accumulate proximate the plasma-processing region of a plasma chamber until the chamber is vented and/or purged. Because of this, there is always the danger of re-introduction of captured particles into the plasma-processing region of the plasma chamber during subsequent pumping and venting of the chamber, leading to the contamination of substrate surfaces.

Therefore, there is a need for an apparatus capable of removing particles from a plasma-processing chamber without significantly increasing chamber cost or decreasing chamber throughput.

### SUMMARY OF THE INVENTION

Embodiments of the present invention provide apparatus and a method for removing charged particles suspended in a plasma-processing chamber. In one embodiment, an apparatus comprises a conductor positioned in a processing region of a plasma-processing chamber and a power supply configured to apply a DC bias to the conductor when plasma is present in the processing region. In another embodiment, a substrate processing chamber comprises a gas source coupled to the processing chamber, a plasma power supply configured to produce a plasma in a processing region of the processing chamber, a conductor positioned in the processing region, and a power supply configured to apply a DC bias to the conductor. In either embodiment, the conductor may comprise aluminum, and the power supply may be controlled by a plasma controller of the plasma-processing chamber.

The method, according to one embodiment, comprises positioning a substrate in a processing chamber, flowing a processing gas into the processing chamber, generating a plasma in the processing chamber, and applying a DC bias to a particle collection conductor positioned in the processing chamber. The particle collection conductor may be translated from a first side of the chamber to an opposite side of the chamber while the DC voltage is applied to the particle collection conductor.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A (Prior Art) is a partial sectional side view of a plasma chamber 100 incorporating the apparatus described in U.S. Pat. No. 6,893,532.

FIG. 1B (Prior Art) is a perspective sectional view of a particle-collecting electrode positioned in a plasma chamber.

FIG. 2A is a schematic cross-sectional view of a plasma-processing chamber according to one embodiment of the invention.

FIG. 2B is a partial sectional view of a particle collector incorporated into a plasma-processing chamber.

FIG. 3 is a schematic plan view of a plasma-processing chamber that includes a moveable electrode.

FIG. 4 is a flow chart summarizing a method of processing a substrate according to one embodiment of the invention.

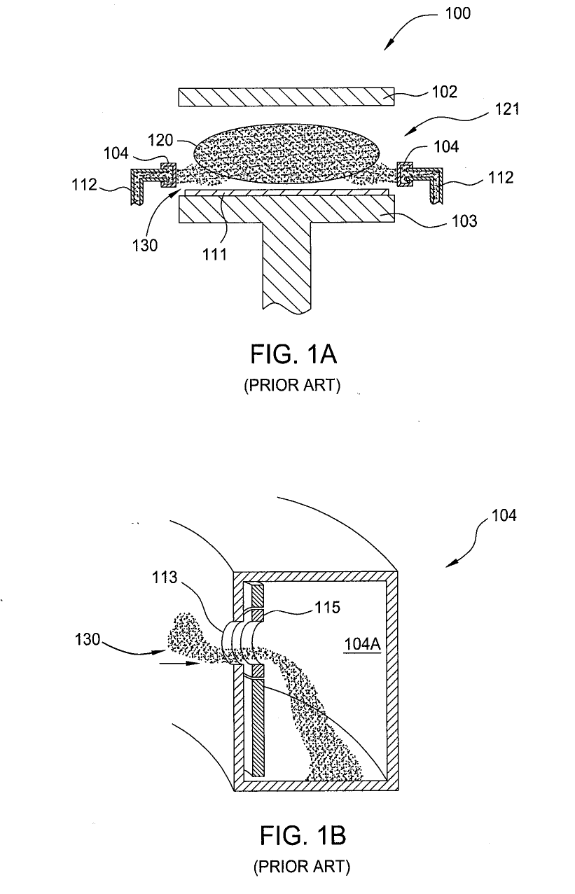

For clarity, identical reference numerals have been used, where applicable, to designate identical elements that are common between figures. It is contemplated that features of one embodiment may be incorporated in other embodiments without further recitation.

### DETAILED DESCRIPTION

Particles that are suspended in the bulk plasma of a plasma-processing chamber are generally charged. Embodiments of the invention contemplate a particle collector that may be positioned in or near the processing region of a plasma-processing chamber to remove such particles during plasma processing of a substrate.

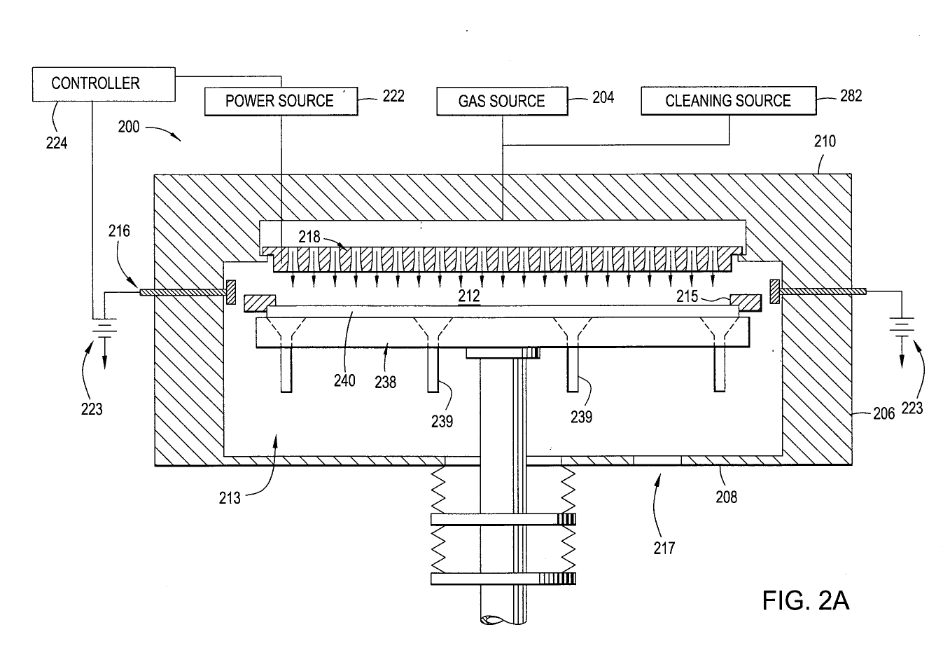

FIG. 2A is a schematic cross-sectional view of a plasma-processing chamber 200 according to one embodiment of the invention. In this example, plasma-processing chamber 200 is a PECVD chamber that may be adapted to benefit from the invention, however PVD, etch, and other plasma-processing chambers may be adapted to benefit from the invention as well. Plasma-processing chamber 200 is available from AKT, a division of Applied Materials, Inc., Santa Clara, Calif.

Plasma-processing chamber 200 is coupled to a gas source 204 and a cleaning source 282 and has walls 206, a bottom 208, and a lid assembly 210 that define the vacuum region 213 of plasma-processing chamber 200. A temperature-controlled substrate support assembly 238 is centrally disposed within the plasma-processing chamber 200 and is adapted to support a substrate 240 during plasma processing.

Substrate support assembly 238 may include lift pins 239, which are adapted to raise substrate 240 off of substrate support assembly 238 when substrate support assembly 238 is lowered. Lift pins 239 contact bottom 208 and, as substrate support assembly 238 is lowered further, a gap is created between substrate 240 and substrate support assembly 238, thereby allowing removal of substrate 240 from plasma-processing chamber 200 by a substrate transfer robot.

The walls 206 support lid assembly 210. In some embodiments, lid assembly 210 may contain a pumping plenum (not shown) that couples vacuum region 213 to an upper exhaust port (not shown). In the embodiment shown, a lower exhaust port 217 may be located in the floor of plasma-processing chamber 200. Lid assembly 210 and substrate support assembly 238 substantially define a plasma-processing region 212, which is configured for plasma processing of substrate 240. Gas distribution plate 218, which is part of lid assembly 210, is configured to provide uniform distribution of process gases into plasma-processing region 212 for the processing of substrate 240 and for in-situ cleaning of interior surfaces of plasma-processing chamber 200. A shadow ring 215 may be configured to rest on a peripheral region of the front surface of substrate 240 during deposition in order to inhibit unwanted deposition on the backside and edge of substrate 240.

For a standard PECVD process, substrate support assembly 238 is electrically grounded and radio frequency (RF) power is supplied by a power source 222 to an electrode positioned within or near the lid assembly 210 to excite gases present in plasma-processing region 212, thereby producing plasma. In the configuration shown in FIG. 2A, gas distribution plate 218 acts as the electrode. The magnitude of RF power for driving the chemical vapor deposition process is generally selected based on the size of the substrate and the particular deposition process in question. Alternatively, very high frequency (VHF) power may be supplied by power source 222 to the electrode.

Gas source 204 provides the reactive gases to plasma-processing chamber 200, such as silane (SiH₄), which are necessary for the PECVD process. Cleaning source 282 typically provides a cleaning agent, such as dissociated fluorine, that may be introduced into the plasma-processing chamber 200 to perform an in-situ cleaning process. Periodic in-situ cleaning, i.e., cleaning of chamber components while the chamber is sealed and under vacuum, removes deposition by-products and films that are formed on internal surfaces of plasma-processing chamber 200 in the course of substrate processing. Examples of surface that require in-situ cleaning include exposed surfaces of substrate support assembly 238, shadow ring 215, and gas distribution plate 218. In-situ cleaning may be conducted at intervals in plasma-processing chamber 200. The frequency of in-situ cleaning of plasma-processing chamber 200 is a function of numerous factors, including the material that is being deposited, the thickness of the material that is being deposited on each substrate, and the composition of the internal chamber components exposed to the deposition process, among others. In some cases, an in-situ clean may be performed after each substrate is processed in plasma-processing chamber 200. In other situations, the in-situ clean is performed after a larger number of substrates has been processed, such as after every 10 or more substrates has been processed.

A particle collector 216 is positioned proximate the periphery of plasma-processing region 212 as shown in FIG. 2A. For clarity, FIG. 2B is a partial sectional view of particle collector 216 incorporated into plasma-processing chamber 200. Particle collector 216 includes an electrical penetration 220 and a collection electrode 219. Electrical penetration 220 is configured to provide an electrically insulated path for electrical wiring to enter processing chamber 200 through wall 206 while maintaining a vacuum-tight seal. Collection electrode 219 is a conductor, such as a metal wire, rod, or band, that consists of a conductive material resistant to the cleaning agents used during in-situ cleaning of plasma-processing chamber 200. In one aspect, collection electrode 219 is an aluminum band, as shown in FIG. 2A, since aluminum is a much more resistant material to fluorine-based cleaning agents than other vacuum-compatible materials, such as stainless steel. In another aspect, collection electrode 219 may be an anodized aluminum material, in order to minimize arcing between collection electrode 219 and gas distribution plate 218 during plasma processing. In yet another aspect, collection electrode 219 may have a texturized surface, for example at least about 40 micro inches, to enhance adhesion of captured-particles to the surface thereof. In this aspect, it is noted that if collection electrode 219 has a texturized surface that is too rough, for example about 500 micro inches, arcing between collection electrode 219 and gas distribution plate 218 may result. For greater durability and reduced arcing potential, collection electrode 219 may be configured as a metal rod or band.

Particle collector 216 and collection electrode 219 may be positioned substantially level with substrate 240, or, as shown in FIG. 2B, between gas distribution plate 218 and deposition surface 241 of substrate 240. The optimal position H of collection electrode 219 relative to substrate 240 for preventing arcing while maximizing particle capture efficiency is a function of numerous factors, including voltage applied to collection electrode 219, the distance between collection electrode 219 and substrate 240, and the operating pressure of plasma-processing chamber 200 during processing, among others. The optimal distance therebetween may be determined by one skilled in the art based on these and other factors.

Collection electrode 219 is electrically coupled, via electrical penetration 220, to a DC power source 223, and is electrically isolated from ground potential. In one aspect, a single particle collector 216, consisting of a single collection electrode 219, is positioned around all or most of the periphery of substrate 240. In another aspect, multiple particle collectors may be positioned at different locations around the periphery of substrate 240. In this aspect, a single DC power source 223 or multiple DC power sources (not shown) may be used. In one configuration, DC power source 223 may be controlled by a controller 224 that also operates power source 222 to ensure adequate synchronization between plasma generation in processing region 212 and the biasing of collection electrode 219. The magnitude of DC bias applied to collection electrode 219 may be between about 10 V and about 500 V. The optimal voltage is a function of chamber pressure, distance between collection electrode 219 and gas distribution plate 218, substrate size, and plasma power, among other factors.

Gas distribution plate 218 may be configured with an insulator stand-off 221 to electrically isolate gas distribution plate 218 from wall 206 and particle collector 216. In one aspect, insulator stand-off 221 is configured to extend a distance D inward from the inner surface 206A of wall 206 to minimize the potential for arcing between collection electrode 219 and gas distribution plate 218 during plasma processing.

In operation, particle collector 216 removes charged particles suspended in plasma in processing region 212 during substrate processing. Collection electrode 219 is given a DC bias during plasma processing to draw particles out of processing region 212 prior to plasma being extinguished. In so doing, the number of particles that contaminate deposition surface 241 of substrate 240 is reduced. Because the magnitude of charge accumulated on a particle suspended in plasma may be somewhat proportional to the size of the particle, it is also believed that the largest particles, which are generally the most damaging to a substrate surface, are removed with greater efficiency. This is due to the greater electromotive force generated by the collection electrode on the larger, more highly charged particles in the plasma.

Due to the proximity of collection electrode 219 to processing region 212, collection electrode 219 is efficiently cleaned of captured particles during each in-situ clean of the plasma-processing chamber. Because of this, unwanted particles are not accumulated near processing region 212, thereby eliminating the possibility of recontaminating processing region 212 with particles from collection electrode 219. This approach efficiently removes and eliminates particles from collection electrode 219 and plasma-processing chamber 200, unlike the pumping and purging procedures contemplated by the prior art. Moreover, because no additional procedures are necessary for particle removal with the present invention, such as purging and pumping down the processing region to clean a collection electrode, throughput of the processing chamber is unaffected. Chamber cost and complexity are also left largely unaffected with the present invention because the only additional hardware required is relatively simple. No modifications that substantially increase cost and pump-down time of the chamber are necessary, such as vacuum lines, vacuum pumps, or extra chambers.

In another embodiment, a moveable collection electrode is contemplated to further increase the efficiency of particle removal from plasma during substrate processing. Because the force exerted on a charged particle by a collection electrode is a function of the distance between the particle and the electrode, particles suspended in the center of a plasma-processing region are less likely to be captured by an electrode disposed on the periphery of the plasma-processing region. Hence, by translating a particle-capturing electrode through a plasma-processing region, particle capture efficiency may be greatly increased.

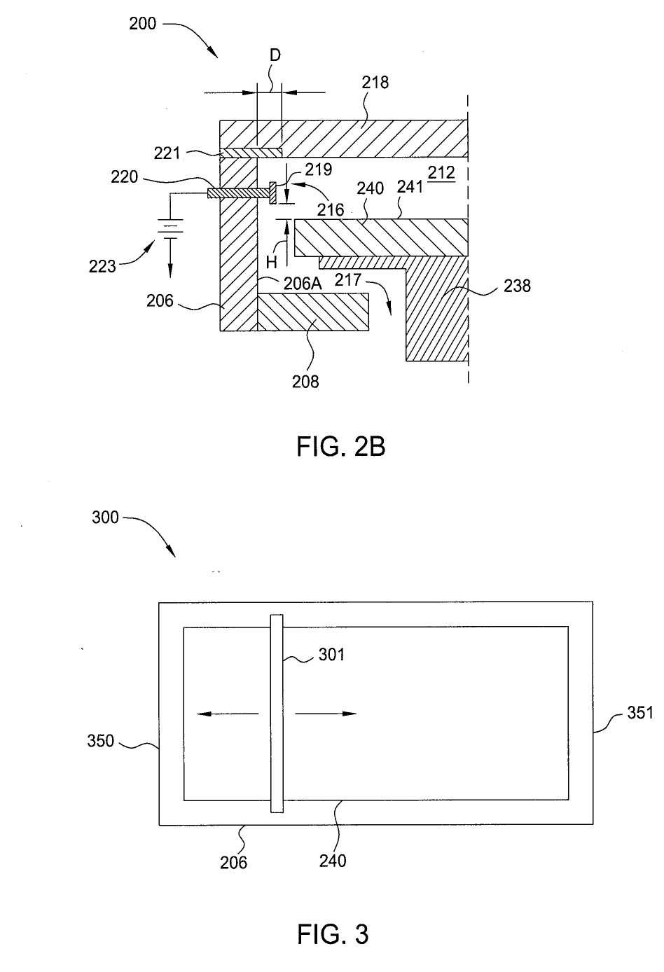

FIG. 3 is a schematic plan view of a plasma-processing chamber 300 that includes a moveable electrode 301, which is configured to translate from a first side 350 of plasma-processing chamber 300 to a second side 351. In so doing, moveable electrode 301 passes over the entire surface of substrate 240 during plasma processing, thereby allowing the efficient capture of particles suspended over substrate 240 before plasma is extinguished. In one configuration, moveable electrode 301 is positioned near the center of plasma-processing chamber 300 during in-situ cleaning of the chamber to ensure that moveable electrode 301 is thoroughly cleaned during this process. In all other aspects, moveable electrode 301 is substantially similar in composition to collection electrode 219.

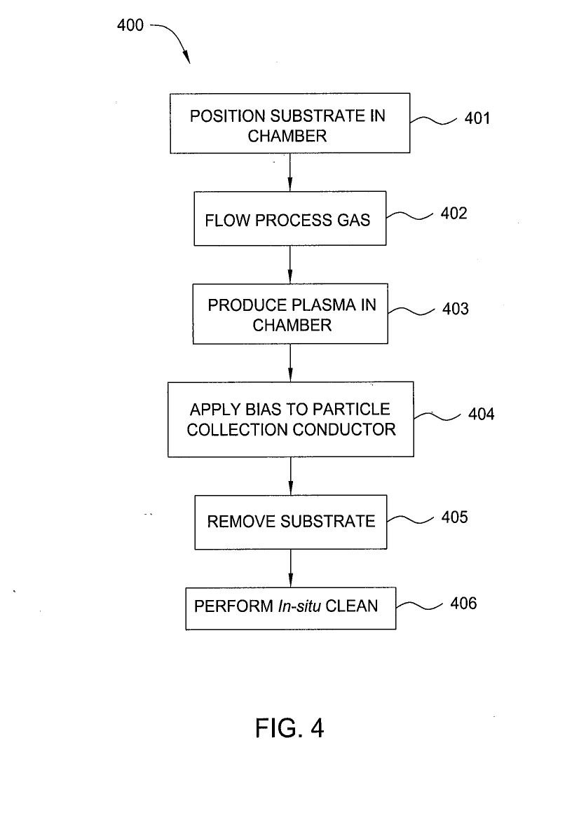

FIG. 4 is a flow chart summarizing a method 400 of processing a substrate according to one embodiment of the invention.

In step 401, a substrate is positioned in a plasma-processing chamber, such as plasma-processing chamber 200, depicted in FIG. 2A. The substrate may be an IC wafer, a glass or plastic flat panel display substrate, or a solar cell substrate, among others. The substrate is positioned using conventional means commonly known in the art of substrate processing, such as with one or more substrate transfer robots.

In step 402, a process gas is flowed into the plasma-processing chamber. For a PECVD process, the process gas may be a reactive gas, such as silane (SiH₄), among others. For a PVD or plasma etch process, the process gas may be a plasma-initiating gas, such as argon (Ar).

In step 403, plasma is generated in the processing region of the plasma-processing chamber for processing the substrate. For a PECVD process, one or more electrodes may be energized with RF power to excite gases in the plasma-processing region. For other processes, such as plasma etch processes, an inductively-coupled RF plasma may be produced in the plasma-processing region.

In step 404, a DC bias is applied to one or more particle collection conductors positioned proximate the substrate being processed. The bias is applied to the particle collection conductor(s) during the plasma processing of the substrate. In one aspect, the bias may also be applied before and/or after plasma processing of the substrate. The magnitude of the DC bias may be between about 10 V and about 500 V. In one aspect, a particle collection conductor is translated through the plasma-processing region of the chamber while the bias is applied to the particle collection conductor.

In step 405, the plasma is extinguished in the plasma-processing chamber and the substrate is removed from the plasma-processing chamber by conventional means commonly known in the art of substrate processing.

In step 406, an in-situ clean is performed on interior surfaces of the plasma-processing chamber, including the particle collection conductor. In one aspect, the in-situ clean is performed after every substrate is processed in the chamber. In another aspect, the in-situ clean is performed after multiple substrates have been processed, for example after each tenth substrate.

While the foregoing is directed to embodiments of the present invention, other and further embodiments of the invention may be devised without departing from the basic scope thereof, and the scope thereof is determined by the claims that follow.

What is claimed is:

1. An apparatus for removing particles from a plasma, comprising:
a conductor positioned in a processing region of a plasma-processing chamber and electrically isolated from ground potential; and
a power supply configured to apply a DC bias to the conductor when plasma is present in the processing region.

2. The apparatus of claim 1, wherein the power supply is configured to apply a bias between about 10 VDC and about 500 VDC.

3. The apparatus of claim 1, wherein the power supply is controlled by a plasma controller of the plasma-processing chamber to synchronize the plasma power supply and the DC power supply.

4. The apparatus of claim 1, wherein the conductor comprises aluminum.

5. The apparatus of claim 1, wherein the conductor comprises a texturized surface of at least about 40 micro inches.

6. The apparatus of claim 4, wherein the conductor comprises an anodized surface.

7. The apparatus of claim 1, wherein the conductor is positioned proximate the periphery of the substrate.

8. The apparatus of claim 7, wherein the conductor is positioned between the substrate and a gas distribution plate of the plasma-processing chamber.

9. An apparatus for processing a substrate, comprising:
a processing chamber;
a gas source selectively coupled to the processing chamber;
a plasma power supply configured to produce a plasma in a processing region of the processing chamber;
a conductor positioned in the processing region and electrically isolated from ground potential; and
a DC power supply configured to apply a bias to the conductor.

10. The apparatus of claim 9, wherein the power supply is configured to apply a bias between about 10 VDC and about 500 VDC.

11. The apparatus of claim 9, wherein the power supply is controlled by a plasma controller of the plasma-processing chamber to synchronize the plasma power supply and the DC power supply.

12. The apparatus of claim 9, wherein the conductor comprises aluminum.

13. The apparatus of claim 9, wherein the conductor is positioned proximate the periphery of the substrate.

14. The apparatus of claim 13, wherein the conductor is positioned between the substrate and a gas distribution plate of the plasma-processing chamber.

15. The apparatus of claim 9, wherein the apparatus further comprises a means for translating the conductor from a first side of the processing chamber to a second side of the processing chamber.

16. The apparatus of claim 9, wherein the plasma power supply is configured to apply RF or VHF power to a gas distribution plate.

17. A particle collection electrode, comprising:
an electrical conductor that comprises a material resistant to fluorine etching, wherein the electrical conductor is adapted for mounting in a processing chamber and configured with an electrical connector for electrically coupling the electrical conductor to a vacuum feed-through.

18. The particle collection electrode of claim 17, wherein the electrical conductor is a band or wire.

19. The particle collection electrode of claim 17, wherein the electrical conductor comprises aluminum.

20. A method for processing a substrate, comprising:
positioning a substrate in a processing chamber;
flowing a processing gas into the processing chamber;
generating a plasma in the processing chamber; and
applying a DC bias to a particle collection conductor positioned in the processing chamber while generating the plasma in the processing chamber.

21. The method of claim 20, further comprising performing an in-situ cleaning process on the particle collection conductor.

22. The method of claim 20, wherein the step of applying a DC bias further comprises applying a DC bias between about 10 V and 500 V.

23. The method of claim 20, further comprising translating the particle collection conductor from a first side of the chamber to an opposite side of the chamber while applying the DC voltage to the particle collection conductor.

24. The method of claim 20, wherein the process of generating a plasma in the processing chamber comprises applying RF or VHF power to a gas distribution plate.
